(19) United States
(12) Patent Application Publication
(10) Pub. No.: US 2011/0297914 A1
(43) Pub. Date: Dec. 8, 2011

(54) GALLIUM NITRIDE-BASED FLIP-CHIP LIGHT-EMITTING DIODE WITH DOUBLE REFLECTIVE LAYERS ON ITS SIDE AND FABRICATION METHOD THEREOF

(75) Inventors: Jiansen ZHENG, Xiamen City (CN); Suhui LIN, Xiamen City (CN); Anhe HE, Xiamen City (CN); Kechuang LIN, Xiamen City (CN)

(73) Assignee: XIAMEN SANAN OPTOELECTRONICS TECHNOLOGY CO., LTD., Xiamen City (CN)

(21) Appl. No.: 13/153,152

(22) Filed: Jun. 3, 2011

(30) Foreign Application Priority Data
Jun. 7, 2010 (CN) 201010200860.1

(51) Int. Cl. H01L 33/06

(52) U.S. Cl. 257/13; 438/29; 257/E33.008

(57) ABSTRACT

The present invention discloses a double-reflective-layer gallium nitride-based flip-chip light-emitting diode with both a distributed Bragg reflector and a metal reflective layer on its side and a fabrication method thereof. The light-emitting diode includes: a sapphire substrate; a buffer layer, an N-GaN layer, a multiple-quantum-well layer and a P-GaN layer stacked on the sapphire substrate in that order; a transparent conductive layer formed on the P-GaN layer; a distributed Bragg reflector formed over a side of the epitaxial layer and the transparent conductive layer; a metal reflective layer formed on the DBR; a P-type ohmic contact electrode formed on the transparent conductive layer; and an N-type ohmic contact electrode formed on the exposed N-GaN layer, wherein the P-type ohmic contact electrode and the N-type ohmic contact electrode are bonded to a heat dissipation substrate through a metal conductive layer and a ball bonder. By arranging a double reflection structure including a DBR and a metal reflective layer on the sloping side of the LED chip, the good reflectivity of the reflective layers can be fully utilized, thereby improving the light-emission efficiency of the LED.

### FIELD OF THE INVENTION

The present invention relates to a gallium nitride (GaN) based light-emitting diode (LED), and particularly to a GaN-based flip-chip LED with double reflective layers on its side and a fabrication method thereof.

### BACKGROUND OF THE INVENTION

With the improvement of power GaN-based LEDs in efficiency, it is clear that GaN-based LEDs are to be a viable replacement for conventional light sources. However, semiconductor light sources are limited in light-emission efficiency and production cost, which makes their wide application problematic. Nowadays, the methods to improve the light-emission efficiency of LEDs generally include: patterned substrate, transparent substrate, Distributed Bragg Reflector (DBR) structure, surface patterning, flip-chip, chip bonding, and laser lift-off techniques. Chinese patent application 200410095820.X discloses a flip-chip light-emitting device and a method for fabricating the same. The flip-chip light-emitting device includes a substrate, an n-type layer, an active layer, a p-type layer, an ohmic contact layer of tin oxide doped with at least one of: antimony, fluorine, phosphorus and arsenic, and a reflective layer of a reflective material. By using the conductive oxide electrode structure with low surface resistivity and high carrier concentration, current-voltage characteristics and durability can be improved. However, the invention uses a single metal layer as the light-emitting reflective layer, which still absorbs some of the light and limits light emission; moreover, the single metal layer is only on the bottom of the chip, i.e., none on the side, therefore, the light-reflection rate of the reflective layer is limited.

### SUMMARY OF THE INVENTION

To solve the problems above, an objective of the present invention is to provide a double-reflective-layer GaN-based flip-chip LED with both a DBR and a metal reflective layer on its side and a fabrication method thereof.

The present invention provides a gallium nitride (GaN) based flip-chip light-emitting diode (LED) with double reflective layers on its side, including:

a sapphire substrate;

a buffer layer and an epitaxial layer formed on the sapphire substrate, the epitaxial layer including an N-GaN layer, a multiple-quantum-well layer and a P-GaN layer;

a transparent conductive layer formed on the P-GaN layer;

a distributed Bragg reflector (DBR) formed over a side of the epitaxial layer and the transparent conductive layer;

a metal reflective layer of an Al—Ag alloy formed on the DBR;

a P-type ohmic contact electrode of a Ti—Au alloy formed on the transparent conductive layer; and

an N-type ohmic contact electrode of an Ni—Au alloy formed on the exposed N-GaN layer,

wherein the P-type ohmic contact electrode and the N-type ohmic contact electrode are bonded to a Si heat dissipation substrate through a Ni—Au alloy metal conductive layer and a Au ball bonder.

The present invention also provides a fabrication method for a gallium nitride (GaN) based flip-chip light-emitting diode (LED) with double reflective layers on its side, including:

1) forming a buffer layer and an epitaxial layer on a sapphire substrate, the epitaxial layer including an N-GaN layer, a multiple-quantum-well layer and a P-GaN layer;

2) forming a transparent conductive layer on the P-GaN layer;

3) mask etching a portion of the mesa with the transparent conductive layer such that the N-GaN layer is exposed;

4) cutting the epitaxial layer and the transparent conductive layer such that the epitaxial layer and the transparent conductive layer have a sloping side;

5) forming a distributed Bragg reflector (DBR) over the side of the epitaxial layer and the transparent conductive layer, the DBR including alternating layers with a high refractive index and with a low refractive index;

6) forming a metal reflective layer on the DBR;

7) forming a P-type ohmic contact electrode on the transparent conductive layer;

8) forming an N-type ohmic contact electrode on the exposed N-GaN layer, thereby finishing fabrication of a GaN-based LED s;

9) providing a heat dissipation substrate, and forming a metal conductive layer and a ball bonder on the heat dissipation substrate for eutectic soldering;

10) soldering the GaN-based LED substrate to the heat dissipation substrate; and

11) thinning and polishing the sapphire substrate, and dicing to obtain separate LED chips.

In the present invention, the material of the transparent conductive layer may be any at least one of: ITO, ZnO, In-doped ZnO, Al-doped ZnO and Ga-doped ZnO; the material of the N-type ohmic contact electrode may be any at least one of: Ni—Au, Cr—Pt—Au and Ti—Al—Ti—Au; the material of the P-type ohmic contact electrode may be any at least one of: Ti—Au, Pt—Au and Ti—Al—Ti—Au; the material of the layer with a high refractive index in the DBR may be any at least one of: TiO, TiO₂, Ti₃O₅, Ti₂O₃, Ta₂O₅ and ZrO₂; the material of the layer with a low refractive index in the DBR may be any at least one of: SiO₂, SiNₓ and Al₂O₃; the material of the metal reflective layer may be any at least one of: Al and Ag; the material of the metal conductive layer may be any at least one of: Al, Au and Ni; the material of the ball bonder may be Au or an Au alloy; the GaN-based LED substrate may be bonded to the heat dissipation substrate by eutectic soldering or fusion bonding.

The technical solution of the present invention has the advantages that: by arranging a double reflection structure including a DBR and a metal reflective layer on the sloping side of the LED chip, the good reflectivity of the reflective layers can be fully utilized, thereby improving the light-emission efficiency of the LED.

### BRIEF DESCRIPTION OF THE DRAWINGS

FIGS. 1 to 8 illustrates a process for fabricating a GaN-based flip-chip LED according to the present invention with a cross-sectional view.

The reference numerals used in the accompanying drawings include:

| | |
|---|---|
| 1. | sapphire substrate; |
| 2. | buffer layer; |
| 3. | N-GaN layer; |
| 4. | multiple-quantum-well layer; |
| 5. | P-GaN layer; |
| 6. | transparent conductive layer; |
| 7. | DBR; |
| 8. | Al—Ag alloy metal reflective layer; |
| 9. | P-type ohmic contact electrode; |
| 10. | N-type ohmic contact electrode; |
| 11. | heat dissipation substrate; |
| 12. | Ni—Au alloy metal conductive layer; |
| 13. | Au ball bonder. |

### DESCRIPTION OF THE PREFERRED EMBODIMENTS

The present invention will be further described hereinafter with reference to the embodiments and the accompanying drawings.

A fabrication method for a GaN-based flip-chip LED with double reflective layers on its side includes the following steps:

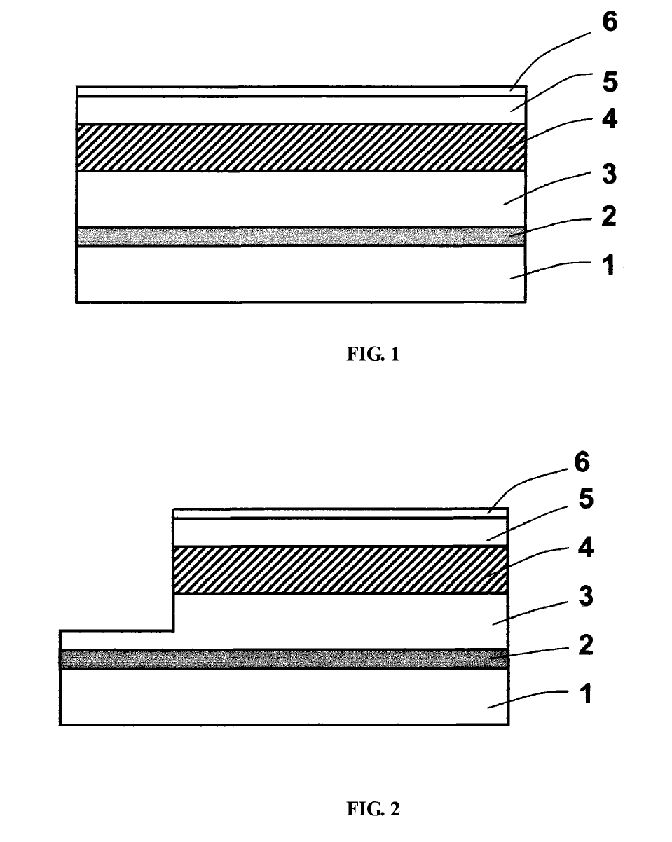

as shown in FIG. 1, forming a buffer layer 2 and an epitaxial layer on a sapphire substrate 1 in that order, with the epitaxial layer includes an N-GaN layer 3, a multiple-quantum-well layer 4 and a P-GaN layer 5; and forming an ITO transparent conductive layer 6 on the P-GaN layer 5;

as shown in FIG. 2, mask etching a portion of the mesa with the ITO transparent conductive layer 6 such that the N-GaN layer 3 is exposed;

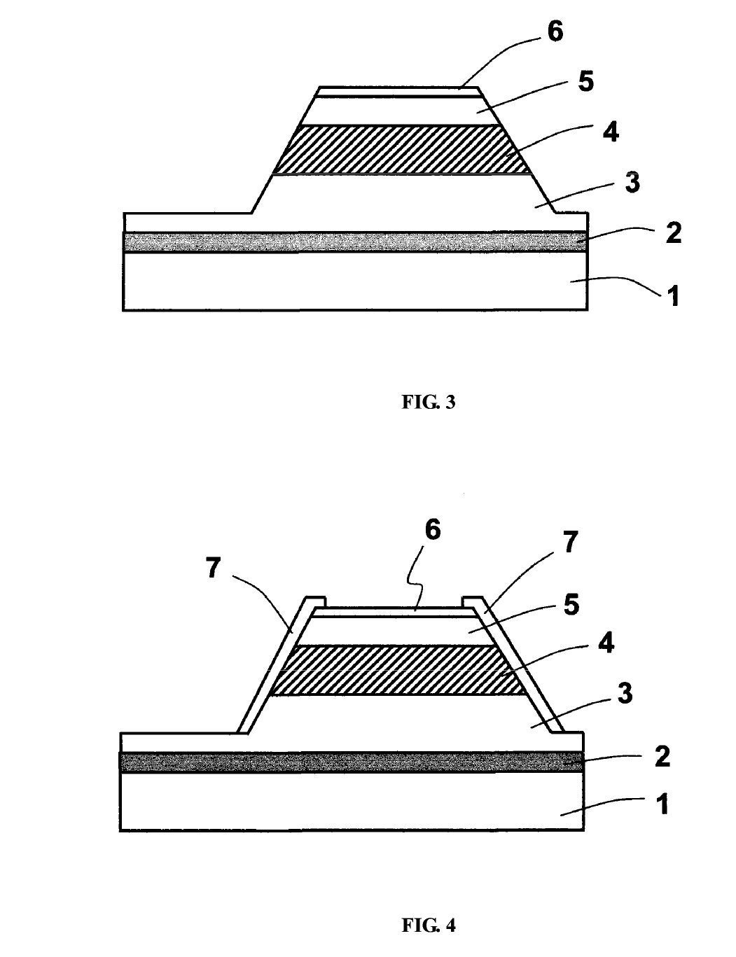

as shown in FIG. 3, cutting the epitaxial layer and the ITO transparent conductive layer 6 such that the epitaxial layer and the ITO transparent conductive layer 6 have a sloping side;

as shown in FIG. 4, forming a DBR 7 over the sloping side of the epitaxial layer and the ITO transparent conductive layer 6, with the DBR 7 includes alternating layers of TiO₂ with a high refractive index and SiO₂ with a low refractive index;

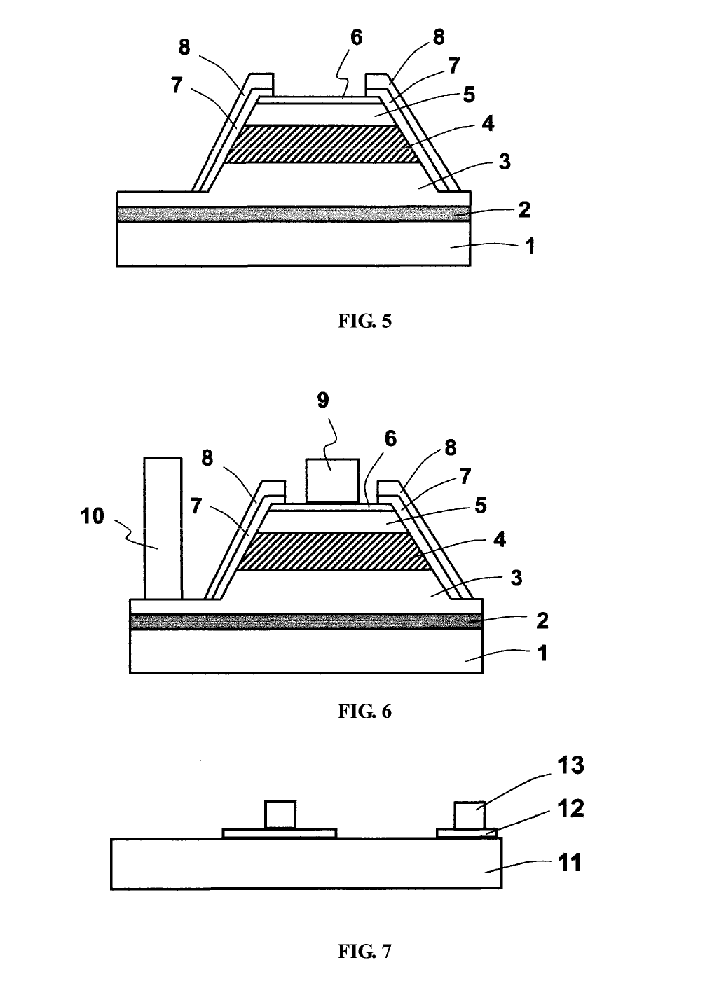

as shown in FIG. 5, forming an Al—Ag alloy metal reflective layer 8 on the DBR 7;

as shown in FIG. 6, forming a P-type ohmic contact electrode 9 on the ITO transparent conductive layer 6, with the material of the P-type ohmic contact electrode 9 being a Ti—Au alloy; and forming an N-type ohmic contact electrode 10 on the N-GaN layer 3, with the material of the N-type ohmic contact electrode 10 being a Ni—Au alloy, thereby finishing fabrication of a GaN-based LED substrate;

as shown in FIG. 7, providing a Si heat dissipation substrate 11, and forming an Ni—Au alloy metal conductive layer 12 and an Au ball bonder 13 on the heat dissipation substrate 11 for eutectic soldering;

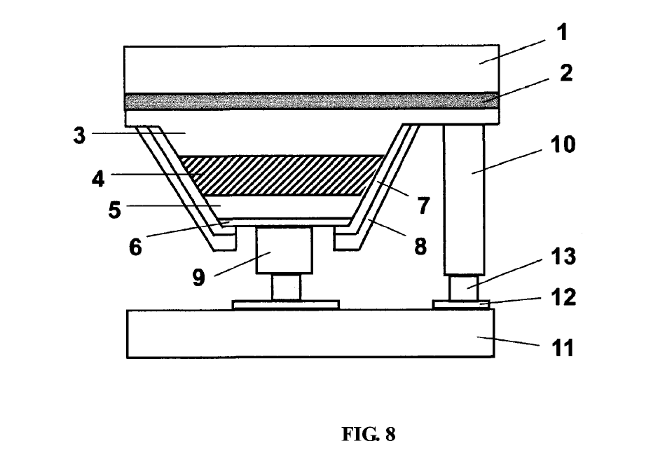

as shown in FIG. 8, soldering the formed GaN-based LED substrate to the Si heat dissipation substrate 11 by eutectic soldering; thinning and polishing the sapphire substrate 1 and dicing to obtain separate LED chips, thereby finishing the fabrication process of the present invention.

FIG. 8 shows a GaN-based flip-chip LED chip according to the fabrication method above, including: a sapphire substrate 1; a buffer layer 2, an N-GaN layer 3, a multiple-quantum-well layer 4 and a P-GaN layer 5 stacked on the sapphire substrate 1 in that order; an ITO transparent conductive layer 6 formed on the P-GaN layer 5; a DBR 7 formed over a sloping side of the epitaxial layer and the transparent conductive layer 6, wherein the DBR 7 includes alternating layers of TiO₂ with a high refractive index and SiO₂ with a low refractive index; an Al—Ag alloy metal reflective layer 8 formed on the DBR 7; a P-type ohmic contact electrode 9 made of an Ti—Au alloy formed on the ITO transparent conductive layer 6; an N-type ohmic contact electrode 10 made of an Ni—Au alloy formed on the exposed N-GaN layer 3, wherein the P-type ohmic contact electrode 9 and the N-type ohmic contact electrode 10 are bonded to a Si heat dissipation substrate 11 through an Ni—Au alloy metal conductive layer 12 and a Au ball bonder 13.

The embodiments above are for descriptive purpose only, and should not be interpreted as limiting the scope of the present invention. A variety of alternations and variations can be made by those skilled in the art without departing from the scope of the invention. Therefore, all the equivalent technical solutions fall within the scope of the invention, which is defined by the claims.

1. A gallium nitride (GaN) based flip-chip light-emitting diode (LED) with double reflective layers on its side, comprising:
a sapphire substrate;
a buffer layer and an epitaxial layer formed on the sapphire substrate, the epitaxial layer comprising an N-GaN layer, a multiple-quantum-well layer and a P-GaN layer;
a transparent conductive layer formed on the P-GaN layer;
a distributed Bragg reflector (DBR) formed over a side of the epitaxial layer and the transparent conductive layer;
a metal reflective layer of an Al—Ag alloy formed on the DBR;
a P-type ohmic contact electrode of a Ti—Au alloy formed on the transparent conductive layer; and
an N-type ohmic contact electrode of an Ni—Au alloy formed on the exposed N-GaN layer,
wherein the P-type ohmic contact electrode and the N-type ohmic contact electrode are bonded to a Si heat dissipation substrate through a Ni—Au alloy metal conductive layer and a Au ball bonder.

2. A fabrication method for a gallium nitride (GaN) based flip-chip light-emitting diode (LED) with double reflective layers on its side, comprising:
1) forming a buffer layer and an epitaxial layer on a sapphire substrate, the epitaxial layer comprising an N-GaN layer, a multiple-quantum-well layer and a P-GaN layer;
2) forming a transparent conductive layer on the P-GaN layer;
3) mask etching a portion of the mesa with the transparent conductive layer such that the N-GaN layer is exposed;
4) cutting the epitaxial layer and the transparent conductive layer such that the epitaxial layer and the transparent conductive layer have a sloping side;
5) forming a distributed Bragg reflector (DBR) over the side of the epitaxial layer and the transparent conductive layer, the DBR comprising alternating layers with a high refractive index and with a low refractive index;
6) forming a metal reflective layer on the DBR;
7) forming a P-type ohmic contact electrode on the transparent conductive layer;
8) forming an N-type ohmic contact electrode on the exposed N-GaN layer, thereby finishing fabrication of a GaN-based LED substrate;
9) providing a heat dissipation substrate, and forming a metal conductive layer and a ball bonder on the heat dissipation substrate for eutectic soldering;
10) soldering the GaN-based LED substrate to the heat dissipation substrate; and
11) thinning and polishing the sapphire substrate, and dicing to obtain separate LED chips.

3. The fabrication method for a GaN-based flip-chip LED with double reflective layers on its side according to claim 2, wherein, the material of the transparent conductive layer is any at least one of: ITO, ZnO, In-doped ZnO, Al-doped ZnO and Ga-doped ZnO.

4. The fabrication method for a GaN-based flip-chip LED with double reflective layers on its side according to claim 2, wherein, the material of the N-type ohmic contact electrode is any at least one of: Ni—Au, Cr—Pt—Au and Ti—Al—Ti—Au.

5. The fabrication method for a GaN-based flip-chip LED with double reflective layers on its side according to claim 2, wherein, the material of the P-type ohmic contact electrode is any at least one of: Ti—Au, Pt—Au and Ti—Al—Ti—Au.

6. The fabrication method for a GaN-based flip-chip LED with double reflective layers on its side according to claim 2, wherein, the material of the layer with the high refractive index in the DBR is any at least one of: TiO, TiO₂, Ti₃O₅, Ti₂O₃, Ta₂O₅ and ZrO₂.

7. The fabrication method for a GaN-based flip-chip LED with double reflective layers on its side according to claim 2, wherein, the material of the layer with the low refractive index in the DBR is any at least one of: SiO₂, SiNₓ and Al₂O₃.

8. The fabrication method for a GaN-based flip-chip LED with double reflective layers on its side according to claim 2, wherein, the material of the metal reflective layer is any at least one of: Al and Ag.

9. The fabrication method for a GaN-based flip-chip LED with double reflective layers on its side according to claim 2, wherein, the material of the metal conductive layer is any at least one of: Al, Au and Ni.

10. The fabrication method for a GaN-based flip-chip LED with double reflective layers on its side according to claim 2, wherein, the material of the ball bonder is Au or an Au alloy.

11. The fabrication method for a GaN-based flip-chip LED with double reflective layers on its side according to claim 2, wherein, the GaN-based LED substrate is bonded to the heat dissipation substrate by eutectic soldering or fusion bonding.
